(19) United States
(12) Patent Application Publication
(10) Pub. No.: US 2016/0373191 A1
(43) Pub. Date: Dec. 22, 2016

(54) RESOLUTION OF MODE HOPPING IN OPTICAL LINKS

(71) Applicant: Kotura, Inc., Monterey Park, CA (US)

(72) Inventors: Saeed Fathololoumi, San Gabriel, CA (US); Dazeng Feng, El Monte, CA (US); Amir Ali Tavallaee, Los Angeles, CA (US); Jacob Levy, Sierre Madre, CA (US); Pegah Seddighian, Pasadena, CA (US); Mehdi Asghari, Pasadena, CA (US)

(21) Appl. No.: 14/741,391

(22) Filed: Jun. 16, 2015

(51) Int. Cl. H04B 10/564; H04B 10/50; H04B 10/25; H01S 5/02; H01S 5/14

(52) U.S. Cl. CPC H04B 10/564; H01S 5/021; H01S 5/141; H04B 10/2504; H04B 10/503

(57) ABSTRACT

An optical link transmits light between a transmitter and a receiver. The transmitter includes a laser cavity that outputs a laser light signal. The laser cavity is configured such that the mode of the laser light signal hops during operation of the optical link. The transmitter outputs an output light signal that includes light from the laser light signal. The output light signal travels a data travel distance before being received at the receiver. The data travel distance is greater than 0 m and less than 1 km and the optical link has a Bit Error Rate less than 10⁻¹². In some instances, the laser cavity is an external cavity laser.

### FIELD

The present invention relates to optical systems and more particularly to optical devices having a laser cavity.

### BACKGROUND

Lasers are commonly used as the source of light signals in optical communications systems. These lasers are often integrated onto optical chips and/or onto optoelectronic chips. The laser cavities in these lasers can be external cavity lasers configured to output a light signal with a single wavelength or a single longitudinal cavity mode. One of the challenges with these lasers is mode hopping. Mode hopping refers to shift in output light wavelength when laser switches from one longitudinal mode to another. The change between modes is associated with an undesirable discrete change in the wavelength (and sometimes power) of the light signal output by the laser. These changes are a source of bit error in optical links.

The mode hopping can be a result of influences that change the index of refraction of the media through which the light signals are guided in the laser cavity. Examples of influences that can cause these effects are temperature changes, changes in the level of electrical current applied to the laser cavity, or aging of the gain medium. In order to address these problems, many of these devices include temperature control devices such as heaters and/or other feedback control devices for stabilizing the indices of refraction of the media through which the light signals are guided. These temperature control devices and/or other feedback control devices increase the complexity, cost, and power consumption of the device.

### SUMMARY

An optical link transmits light between a transmitter and a receiver. The transmitter includes a laser cavity that outputs a laser light signal. The laser cavity is configured such that a longitudinal cavity mode hop may occur operation of the optical link. The transmitter outputs an output light signal that includes light from the laser light signal. The output light signal travels a data travel distance before being received at the receiver. The data travel distance is greater than 0 and less than 1 km and the optical link has a Bit Error Rate less than 10⁻¹². In some instances, the laser cavity is an external cavity laser.

An optical system has a laser cavity on a substrate. The laser cavity outputs a laser light signal where one or more mode hops can occur. The laser cavity has one, two, or three conditions selected from a group consisting of a wavelength error that is greater than 0.15 nm and less than 0.25 nm for at least one of the mode hops, a power variation that is greater than −4 dBm and less than 0.2 dBm for at least one of the mode hops, and a SideMode Suppression Ratio (SMSR) that is less than 100 dB, and greater than 30 dB.

### BRIEF DESCRIPTION OF THE FIGURES

FIG. 1 is a topview of an optical device that includes a laser cavity.

FIG. 2A shows a portion of a device constructed according to FIG. 1. The portion of the device shown in FIG. 2A includes a Bragg grating that serves as a partial reflection device. The Bragg grating includes recesses extending into a top of a ridge waveguide.

FIG. 2B shows a portion of a device constructed according to FIG. 1. The portion of the device shown in FIG. 2B includes a Bragg grating that serves as a partial reflection device. The Bragg grating includes recesses extending into a top of a ridge waveguide and also into slab regions adjacent to the ridge.

FIG. 2C shows a portion of a device constructed according to FIG. 1. The portion of the device shown in FIG. 2C includes a Bragg grating that serves as a partial reflection device. The Bragg grating includes recesses extending into he lateral sides of a ridge waveguide.

FIG. 3A shows the output profile for an optical device having a first laser cavity constructed according to FIG. 1 with a Bragg grating constructed according to FIG. 2A. The output profile shows the optical power output by the laser as a function of wavelength.

FIG. 3B shows the optical power transmitted by a Bragg grating during operation of the laser cavity as a function of bias current application to the gain medium. The data is for the same device used to generate FIG. 3A.

FIG. 3C is a graph of the wavelength versus the applied current for the device used to generate FIG. 3B

FIG. 4A is a topview of a transmitter that includes the device of FIG. 1.

FIG. 4B illustrates an optical link that includes the transmitter of FIG. 4A.

FIG. 5A through FIG. 5D illustrate the portion of a multi-channel device having an interface between a cavity waveguide and a gain element. FIG. 5A is a topview of the multi-channel device.

FIG. 5B is a cross section of the cavity waveguide shown in FIG. 5A taken along the line labeled B.

FIG. 5C is a cross section of the multi-channel device shown in FIG. 5A taken along a line extending between the brackets labeled C in FIG. 5A.

FIG. 5D is a cross section of the multi-channel device shown in FIG. 5A taken along a line extending between the brackets labeled D in FIG. 5A.

FIG. 6A is a schematic for a receiver that suitable for use in an optical link.

FIG. 6B is a topview of a portion of a receiver that is built on a silicon-on-insulator wafer and that includes a light sensor.

FIG. 6C is a cross section of the light sensor shown in FIG. 6B taken along the line labeled B.

### DESCRIPTION

An optical link includes a transmitter and a receiver. The transmitter includes a laser cavity that experiences one or more mode hops during operation of the laser cavity. The inventors have been able to design the laser cavity such that the mode hops result in an acceptable rate of bit errors for optical links of certain distances. For instance, for optical lengths less than 1 km, the inventors have found that the laser cavity can be designed such that the mode hops produce an optical link with a Bit Error Rate (BER) less than 10⁻¹² or even less than 10⁻¹⁵ even though the laser cavity still experiences mode hops during the operation of the optical link. The tolerance of mode hopping in these optical links permits the use of laser types that are more prone to mode hopping but that are more desirable due to reduced costs and/or complexity. For instance, external cavity lasers can be used in these optical links. Additionally or alternately, the tolerance for mode hopping means that devices that include these laser cavities can optionally exclude power hungry temperature control devices such as heaters and/or other devices for stabilizing the indices of refraction of the media through which the light signals are guided in the laser cavity.

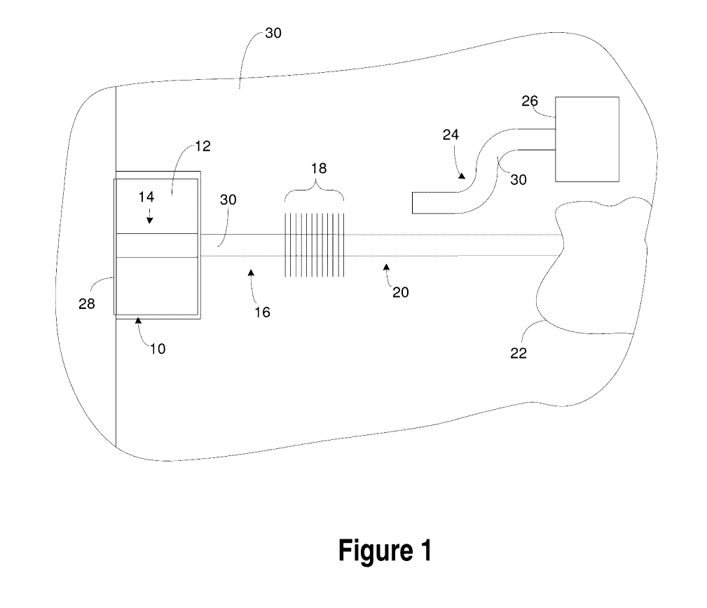

FIG. 1 is a topview of an optical device having a laser cavity that includes a gain element 10. While certain features of the gain element 10 are not shown in FIG. 1, the gain element 10 includes a gain medium 12 that is shown in FIG. 1. A gain waveguide 14 is defined in the gain medium 12. A cavity waveguide 16 provide an optical pathway from the gain waveguide 14 to a partial return device 18. An output waveguide 20 provides an optical pathway from the partial return device 18 to optical components 22 included on the device. The optical components 22 are optional and, in some instances, the output waveguide 20 terminates at a facet located centrally on the device or at an edge of the device so the device can be connected to an optical fiber. Examples of suitable optical components 22 include, but are not limited to, demultiplexers, multiplexers, filters, switches, amplifiers, star couplers, optical fibers, circulators, optical attenuators, etc. One, two, or three waveguides selected from the group consisting of the gain waveguide 14, cavity waveguide 16, and the output waveguide 20 can be a single transverse mode waveguide (singlemode waveguide) or multiple transverse mode waveguide (multimode waveguide).

A coupled waveguide 24 may optionally be optically coupled with the output waveguide 20 such that a portion of the output light signal is coupled into the coupled waveguide 24. The coupled waveguide 24 guides the tapped portion of the output light signal to a light sensor 26. The light sensor 26 is configured to convert the received light signal to an electrical signal. Electronics (not shown) can be in electrical communication with the light sensor 26 and can receive the electrical signal from the light sensor 26. In some instances, the electronics are also in electrical communication with the gain element 10. For instance, the electronics can apply electrical energy to the gain element 10.

During operation of the device, the cavity waveguide 16 carries a laser light signal from the gain medium 12 to the partial return device 18. The partial return device 18 returns a first portion of the laser light signal along its original path and permits a second portion of the laser light signal to enter the output waveguide 20. As a result, the second portion of the laser light signal serves as the light signal output by the laser.

The cavity waveguide 16 carries the first portion of the laser light signal back to the gain waveguide 14. The gain waveguide 14 guides the received first portion of the laser light signal through the gain medium 12 to a reflector 28. The reflector 28 reflects the laser light signal portion such that the first laser light signal portion returns to the gain waveguide 14 and eventually to the partial return device 18. Accordingly, the first laser light signal portion travels through the gain waveguide 14 twice before returning to the partial return device 18. The gain medium 12 in combination with the multiple passes of the laser light signal through the gain medium 12 are the source of optical gain in the laser. Energy can be applied to the gain medium 12 to provide the optical gain. In some instances, the energy is electrical energy provided by the electronics but other forms of energy can be used. The reflector 28 can be highly reflective so substantially all of the first laser light signal portion that is incident on the reflector 28 is returned to the gain waveguide 14.

During the generation of the output light signal, the electronics receive the electrical signal from the light sensor 26. The electronics can also adjust the level of electrical energy applied to the gain element 10 in response to the electrical signal received from the light sensor 26 in a feedback loop. For instance, in the event that the electrical signal from the light sensor 26 indicates that the intensity of the output light signal is above a threshold, the electronics can reduce the electrical energy applied to the gain medium 12 in order to reduce the intensity of the output light signal.

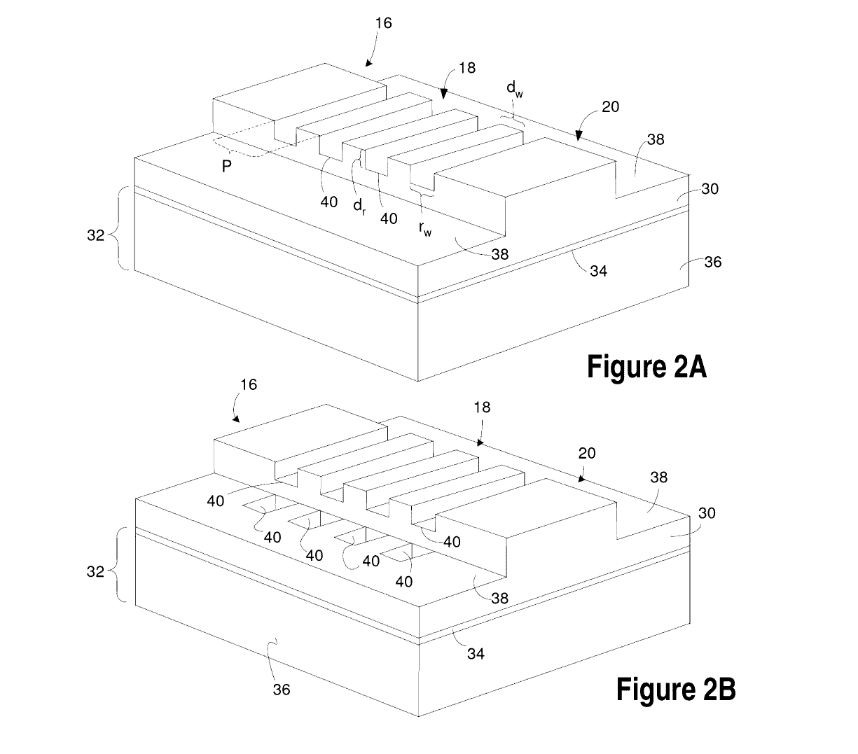

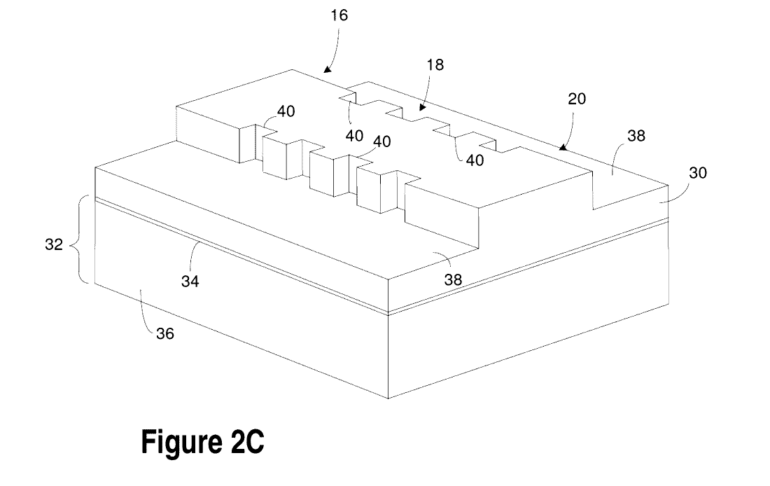

A suitable partial return device 18 is a reflective optical grating such as a Bragg grating. FIG. 2A shows a portion of a device constructed according to FIG. 1. The portion of the device shown in FIG. 2A includes a Bragg grating that serves as the partial reflection device. The device includes a light-transmitting medium 30 positioned on a base 32. The portion of the base 32 adjacent to the light-transmitting medium 30 is configured to reflect light signals from the light-transmitting medium 30 back into the light-transmitting medium 30 in order to constrain light signals in the light-transmitting medium 30. For instance, the portion of the base 32 adjacent to the light-transmitting medium 30 can be an optical insulator 34 with a lower index of refraction than the light-transmitting medium 30. The drop in the index of refraction can cause reflection of a light signal from the light-transmitting medium 30 back into the light-transmitting medium 30. Suitable light-transmitting media include, but are not limited to, silicon, polymers, silica, SiN, GaAs, InP and LiNbO₃.

The base 32 can include the optical insulator 34 positioned on a substrate 36. As will become evident below, the substrate 36 can be configured to transmit light signals. For instance, the substrate 36 can be constructed of a second light-transmitting medium 30 that is different from the light-transmitting medium 30 or the same as the light-transmitting medium 30. The illustrated device is constructed on a silicon-on-insulator wafer. A silicon-on-insulator wafer includes a silicon layer that serves as the light-transmitting medium 30. The silicon-on-insulator wafer also includes a layer of silica positioned on a silicon substrate 36. The layer of silica can serve as the optical insulator 34 and the silicon substrate 36 can serve as the substrate 36.

The illustrated portion of the device shows a Bragg grating at an interface between the cavity waveguide 16 and the output waveguide 20. A ridge of the light-transmitting medium 30 extends outward from slab regions 38 of the light-transmitting medium 30. The ridge partially defines each of the waveguides. For instance, the ridges and the base 32 together define a portion of a light signal-carrying region where light signals are constrained within each of the waveguides. When the device is constructed on a silicon-on-insulator wafer, the silica that serves as the insulator 34 has an index of refraction that is less than an index of refraction of the silicon light-transmitting medium 30. The reduced index of refraction prevents the light signals from entering the substrate 36 from the silicon. Different waveguides on the device can have different dimensions or the same dimensions.

Recesses 40 extend into the top of the ridge. The recesses 40 are filled with a medium having a lower index of refraction than the light-transmitting medium 30. The medium can be a solid or a gas such as air. Accordingly, the recesses 40 provide the variations in the index of refraction of the waveguide that allow the recesses 40 to act as a Bragg grating. The Bragg grating is illustrated with only four recesses 40 in order to simplify the illustration. However, the Bragg grating can include more than four recesses 40. In some instances, the recesses 40 are arranged so as to form a periodic pattern in the ridge. The period is labeled P in FIG. 2A.

The recesses 40 need not extend only into top of the ridge. For instance, the recesses 40 can also extend into the slab regions 38 of the light-transmitting medium 30 as shown in FIG. 2B. Although FIG. 2B shows the recesses extending into the slab regions 38 of the light-transmitting medium 30 on one side of the ridge, the recesses can extend into the slab regions 38 of the light-transmitting medium 30 on both sides of the ridge. Alternately, the recesses 40 can extend into one or both of the lateral sides of the ridge as shown in FIG. 2C. The recesses 40 can also be combinations of the above arrangements. For instance, the recesses 40 can extend into the lateral sides of the ridge and also the into the slab regions 38 of the light-transmitting medium 30. Alternately, each recess 40 can extend into top of the ridge, into the lateral sides of the ridge and also the into the slab region 38 of the light-transmitting medium 30.

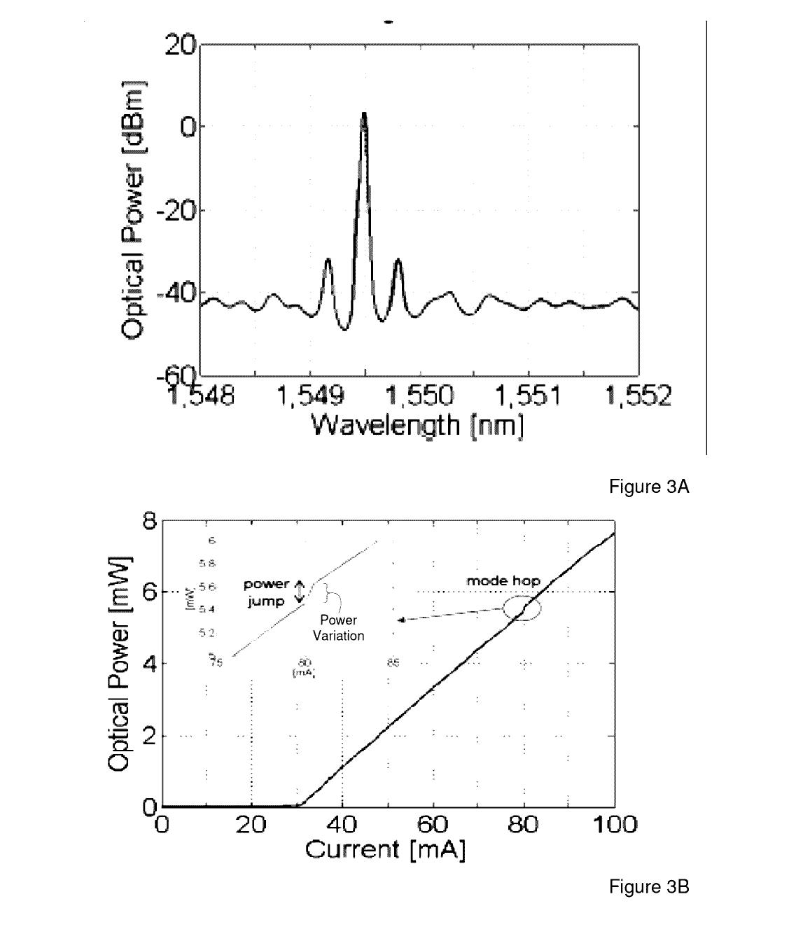

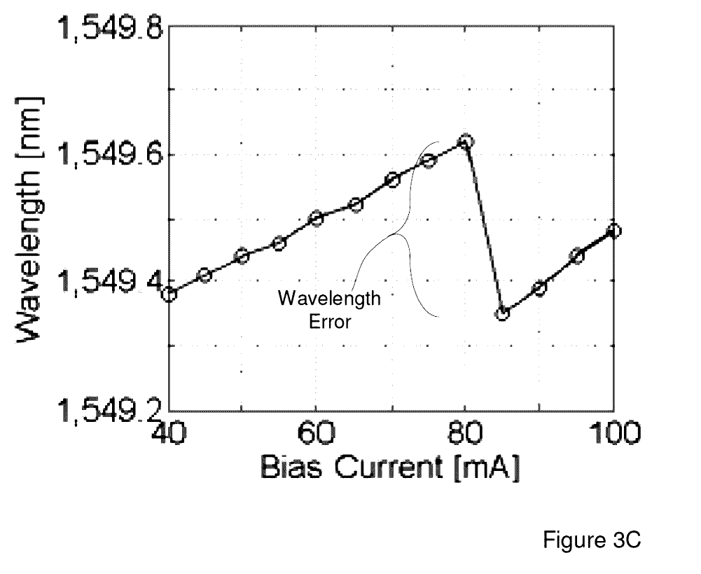

FIG. 3A present an output profile for an optical device having a first laser cavity constructed according to FIG. 1 with the partial return device being a Bragg grating constructed according to FIG. 2A. The output profile shows the optical power output from the laser cavity as a function of wavelength. The output includes light in multiple different modes. The mode with the most intense wavelength output by the laser cavity is shown at a wavelength of about 1549.50 nm with an intensity (or power) of about 3.34 dBm. The second most intense mode is shown at a wavelength of about 1549.20 nm and has an intensity (or power) of about −31.79 dBm.

Hopping between the modes of FIG. 3A can be illustrated by increasing the level of current applied to the laser. For instance, FIG. 3B shows the optical power transmitted by the Bragg grating during operation of the laser cavity as a function of bias current application to the gain medium. As the applied bias increases, the optical power increases but shows a sudden increase at around 80 mA. This increase is a result of the laser cavity hopping between modes illustrated in FIG. 3A. The change in power due to a mode hop is the power variation as labeled in FIG. 3B. Although FIG. 3A illustrates a single mode hop, the power variation can be different for different mode hops.

FIG. 3C is a graph of the wavelength versus the applied current for the device used to generate FIG. 3B. The wavelength on the x-axis of FIG. 3C is the most intense wavelength in the output of the cavity. The mode hop evident in FIG. 3B is evident in FIG. 3C as a drop in the wavelength. The amount of the wavelength drop is labeled “wavelength error” in FIG. 3C. As is evident in FIG. 3C, the wavelength error can be different for different mode hops.

A laser cavity is generally associated with an operational temperature range and/or an operational applied current range. For instance, a laser cavity constructed according to FIG. 1 is generally configured to operate in a temperature range greater than 55° C. and/or less than 65° C. and/or at an applied current level greater than 75 mA and/or less than 100 mA. In some instances, the laser cavity experiences more than 1, 2, or 3 and/or fewer than 3, 4, or 5 mode hops across the operational temperature range. Additionally or alternately, the laser cavity experiences more than 1, 2, or 3 and/or fewer than 3, 4, or 5 mode hops across the operational applied current range. In some instance, the laser cavity experiences more than 1, 2, or 3 and/or fewer than 3, 4, or 5 mode hops for the functional operational range of the laser cavity (all possible combinations of temperature and applied current in the operational temperature range and in the operational applied current range). Although not illustrated, a device can include one or more components and/or electronics that maintain the laser cavity at a constant temperature and/or apply a constant current to the laser cavity. As a result, in some devices, aging of the gain medium is the only or dominant source of mode hopping.

The laser cavity construction disclosed above is an example of an external cavity laser. An external cavity laser includes a passive region. For instance, the laser cavity guides the light through a medium other than the gain medium where light amplification does not occur at all or does not substantially occur. The region of the laser cavity where light is not amplified can serve as the passive region. As an example, the cavity waveguide 16 and gain waveguides 14 disclosed in the context of FIG. 1 are both included in the laser cavity but each guides the light through a different material. When the cavity waveguide 16 does not guide light through a gain medium, the passive region of the laser cavity can include, consist of, or consist essentially of the cavity waveguide 16. In contrast, lasers such as Distributed FeedBack (DFB) lasers have the partial return device defined in the gain medium. Accordingly, DFB laser cavities guide the light through a material(s) that is/are continuous along the length of the cavity. DFB lasers are generally not plagued with the same degree of mode hopping that is present in external cavity lasers. External cavity lasers are more affordable than DFB lasers and are accordingly more desirable; however, the issues with mode hopping have reduced their adoption into marketable optical systems.

Several variables of the laser cavity can be altered to change the optical characteristics of the laser cavity. For instance, the passive length of the laser cavity can be altered. Additionally or alternately, when the partial return device 18 is a Bragg grating, variables such as the depth of the recesses (dᵣ in FIG. 2A), period, recess width (r_{w} in FIG. 2A), and recess separation (dw in FIG. 2A) can be varied to alter the optical characteristics of the laser cavity. An example of an optical characteristic that can be altered is the power variation due to a mode hop (labeled in FIG. 3B). The value of the power variation can be altered by changing the length of the grating and/or the recess depth (dr in FIG. 2A), and/or recess width (rw in FIG. 2A). Another optical characteristic that can be changed is the “wavelength error” labeled in FIG. 3C. The level wavelength error for all or a portion of the mode hops can be changed by altering the length of the passive section of the laser cavity, grating length, and/or length of the gain medium. Since a Bragg grating can be approximated as a fully or partially reflective mirror located half way along the length of the Bragg grating, when the partial return device 18 is a Bragg grating, the passive length of the laser cavity can be approximated as the length from the facet of the gain medium 12 to the center of the Bragg grating length. Another optical characteristic that can be changed is the SideMode Suppression Ratio (SMSR). The SideMode Suppression Ratio (SMSR) is the intensity drop between the peak intensity of the fundamental mode and the peak intensity of the second most intense mode when the fundamental mode is the most intense mode in the output profile of a laser cavity. For instance, in FIG. 3A, the SMSR is about 35.13 dB. The SMSR can be expressed as the percentage of the intensity of the most intensely output mode that is provided by the mode with the next highest intensity. In FIG. 3A, the mode with the second highest intensity is output at an intensity of about 0.03% of the intensity of the most intensely output mode (the fundamental mode). The SMSR can be changed by altering the depth of the recesses (d_{w} in FIG. 2A) and/or the recess width (r_{w} in FIG. 2A), length of the grating and/or length of the passive section.

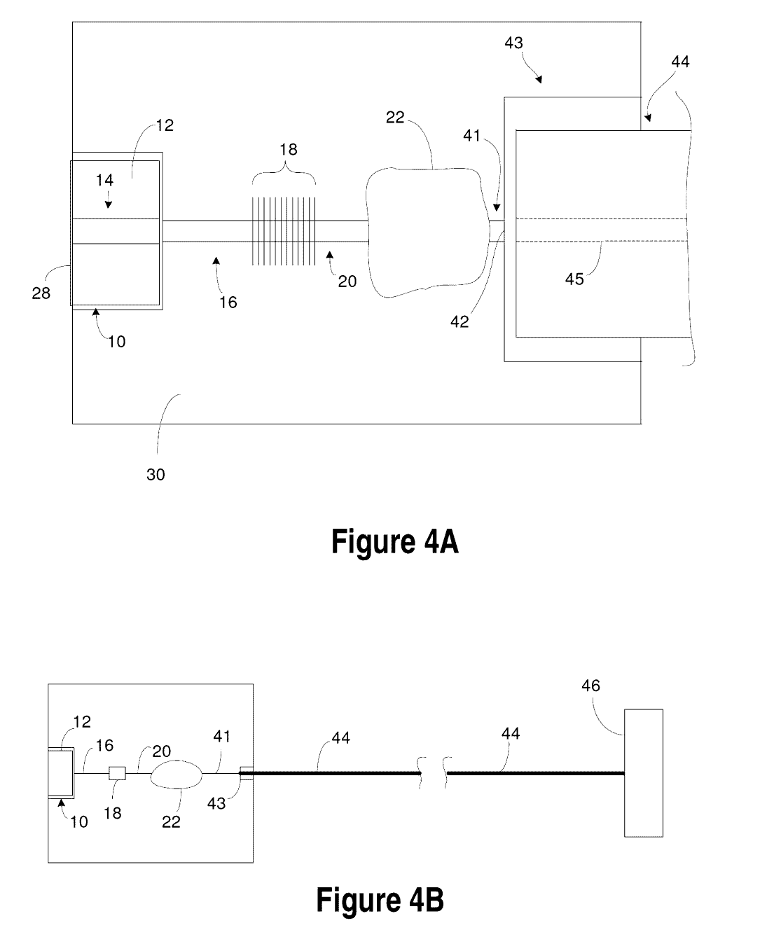

The portion of the device disclosed above can be included in a transmitter. For instance, FIG. 4A is a topview of a transmitter that includes the portion of the device illustrated in FIG. 1. The coupled waveguide 24 and light sensor 26 evident in FIG. 1 are not illustrated on the transmitter of FIG. 4A although the can optionally be present. A device output waveguide 41 carries a device output light signal away from the one or more components 22. The device output light signal can include or consist of a portion of the light from the output light signal. The device output waveguide 41 terminates at a facet 42 included in a fiber recess 43 that extends into the device.

An optical fiber 44 can be positioned in the fiber recess such that the core 45 of the optical fiber is aligned with the facet 42. As a result, the device output light signal can be transmitted through the facet 42 and be received in the core 45 of the optical fiber 44. Although the transmitter of FIG. 4A illustrates the use of a fiber recess 43 to align an optical fiber with a facet on 42 the transmitter, the fiber recess 43 need not be used and other methods, structures and/or systems for aligning an optical fiber with the device can be employed.

The transmitter can be included in an optical link. For instance, FIG. 4B illustrates the transmitter and optical fiber of FIG. 4A included in an optical link where the optical fiber 44 carries the device output light signal to a receiver 46. In some instances, the receiver 46 converts the device output light signal to an electrical signal that can be processed by electronics (not shown). Examples of suitable receivers include, but are not limited to, a photodiode, photodiode arrays, and receiver constructed on optical platforms such as receivers constructed on a silicon-on-insulator wafer.

One measure of the performance of an optical link such as the optical link illustrated in FIG. 4B is the Bit Error Rate (BER) for the optical link. The BER is the number of erroneous bits received at the receiver divided by the total number of bits transferred over the optical link during a studied time interval. BER is a dimensionless performance measure and can be expressed as a percentage. The BER increases as the distance that the data travels increases. For instance, BER increases as the distance between the transmitter and the receiver increases. As an example, in the optical link of FIG. 4B, the BER increases as the length of the optical fiber increases. Accordingly, in some instances, the optical fiber length can represent or approximate the data travel distance for an optical link.

The inventors have found that the laser cavity can be designed so that for certain data travel distances, the BER is at an acceptable level despite the occurrence of mode hops. As an example, for certain data travel distances, the laser cavity can be designed so the BER can be less than 10⁻¹² or 10⁻¹⁵. Further, when Forward Error Correction (FEC) is employed, the laser cavity can be designed so the BER before EFC is less than 10⁻³ or 10⁻⁵. Examples of data travel distances where there BERs can be achieved include distances greater than 0 m, 0.1 m, 1 m or 10 m and/or less than 500 m or less than 1 km. While optical links have traditional been used over longer distances, the adoption of optical links into smaller systems has made these data travel distances more desirable.

As noted above, the above Bit Error Rates (BER) can be achieved through design of the laser cavity. In some instances, the laser cavity is designed such that the wavelength error is greater than greater than 0.15 nm and/or less than 0.30 nm for at least one, for at least a portion, or for all of the mode hops in the functional operational range of the laser cavity or for all mode hops experienced by the laser cavity. In one example, the laser cavity is designed such that the wavelength error is greater than 0.178 nm, or 0.189 nm and/or less than 0.239 nm, 0.245 nm, or 0.257 nm for at least one, for at least a portion, or for all of the mode hops in the functional operational range of the laser cavity or for all mode hops experienced by the laser cavity. As noted above, the desired level of wavelength error for all or a portion of the mode hops can be generally be achieved by altering the length of the passive section of the laser cavity, grating length, and/or length of the gain medium. In some instances, the laser cavity is designed such that the power variation is greater than −10 dBm and/or less than 0.6 dBm for at least one, for at least a portion, or for all of the mode hops in the functional operational range of the laser cavity or for all mode hops experienced by the laser cavity. In one example, the laser cavity is designed such that the power variation is greater than −5 dBm, or −3 dBm and/or less than 0.1 dBm, 0.2 dBm, or 0.3 dBm for at least one, for at least a portion, or for all of the mode hops in the functional operational range of the laser cavity or for all mode hops experienced by the laser cavity. As noted above, the desired value of the power variation for all or a portion of the mode hops can generally be achieved by tuning the length of the grating, the recess depth (dr in FIG. 2A), and/or recess width (rw in FIG. 2A). In some instances, the laser cavity is designed such that the SideMode Suppression Ratio (SMSR) is less than 100 dB and/or greater than 30 dB. In one example, the laser cavity is designed such that the SideMode Suppression Ratio (SMSR) is less than 60 dB and/or greater than 30 dB. As noted above, the desired SMSR level can generally be achieved by altering the depth of the recesses (d_{w} in FIG. 2A), the recess width (r_{w} in FIG. 2A), and/or length of the grating and/or length of the passive section.

In some instances, the laser cavity is configured to have one, two, or three conditions selected from a group consisting of a wavelength error that is greater than 0.15 nm and/or less than 0.30 nm for at least one, for at least a portion, or for all of the mode hops in the functional operational range of the laser cavity or for all mode hops experienced by the laser cavity; a power variation that is greater than −10 dBm and/or less than 0.6 dBm for at least one, for a portion, or for all of the mode hops in the functional operational range of the laser cavity or for all mode hops experienced by the laser cavity; and a SideMode Suppression Ratio (SMSR) that is less than 100 dB and/or greater than 30 dB for at least the functional operational range of the laser cavity. In some instances, a device having the laser cavity with these one, two, or three conditions is included in a optical link having a data travel distance less than 1 km, 500 m, or 100 m. In some instances, the laser cavity is configured to have two of the conditions satisfied for the same mode hop.

In some instances the desired conditions can be achieved using a device where one, two, three, four, or five parameters are selected from the group consisting of a grating greater than 300 um and/or less than 2000 um; a passive section length greater than 150 um and/or less than 800 um; recess depth (dr in FIG. 2A) greater than 200 nm and/or less than 500 nm; recess width (rw in FIG. 2A) greater than 100 nm and/or less than 120 nm, greater than 320 nm and/or less than 350 nm, greater than 500 nm and/or less than 550; and gain medium length greater than 250 um and/or less than 650 um.

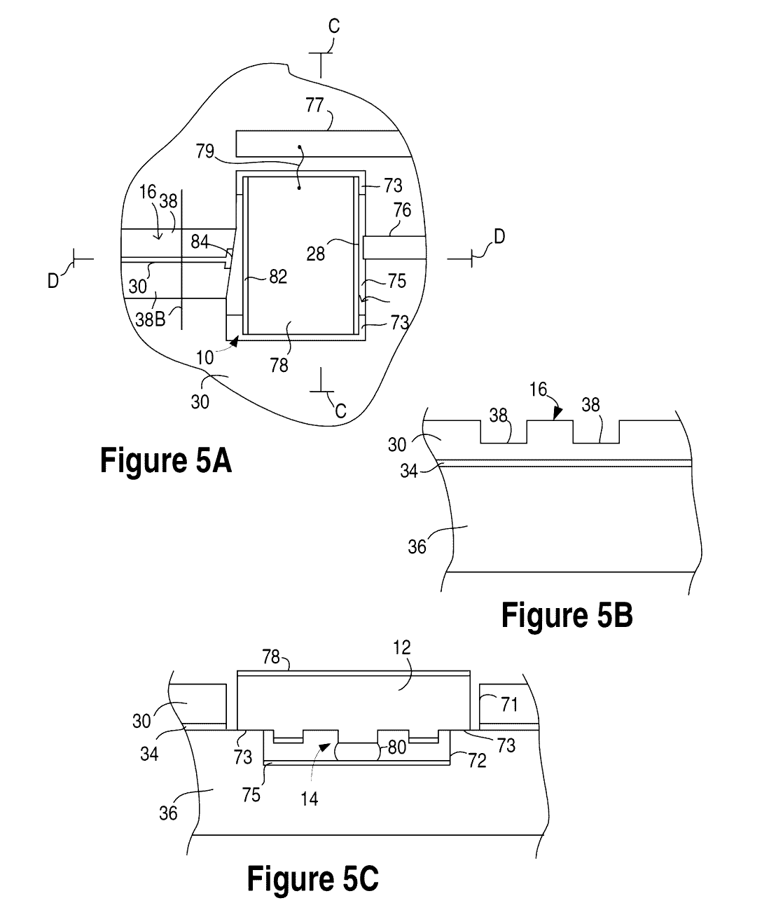

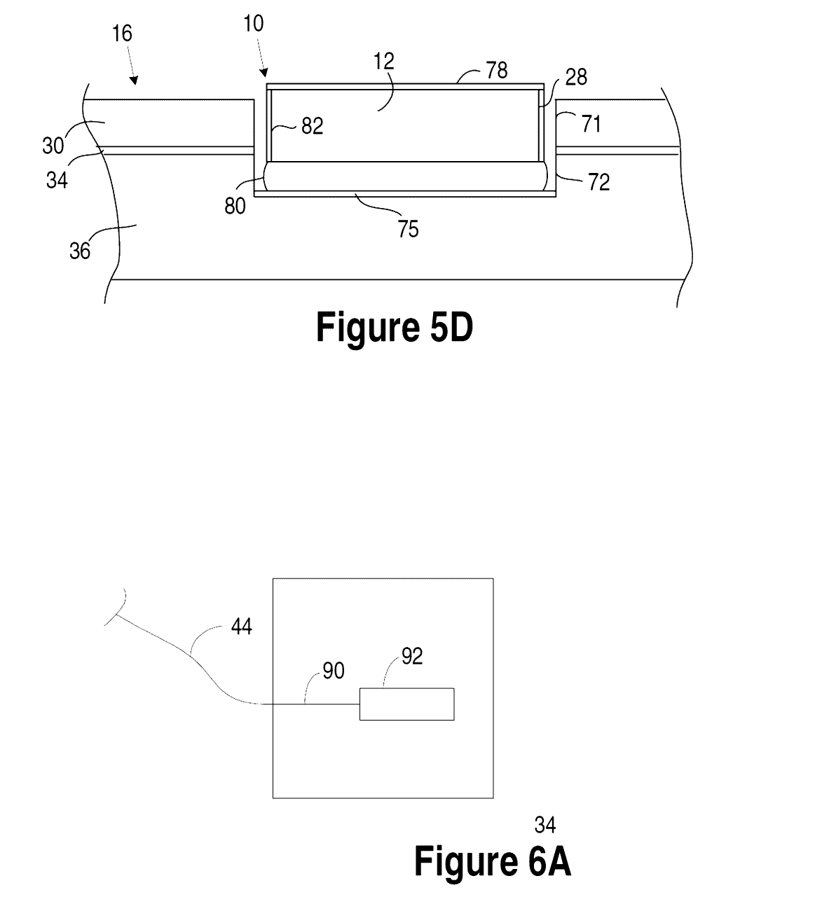

FIG. 5A through FIG. 5D illustrates a suitable structure for interfacing a gain element 10 interfaced with a cavity waveguide 16 as shown in FIG. 1. The device is constructed on a silicon-on-insulator wafer. FIG. 5A is a topview of the device. FIG. 5B is a cross section of the device shown in FIG. 5A taken along the line labeled B. The line labeled B extends through the cavity waveguide 16 disclosed in FIG. 1. Accordingly, FIG. 5B is a cross section of the cavity waveguide 16. FIG. 5C is a cross section of the multi-channel device shown in FIG. 5A taken along a line extending between the brackets labeled C in FIG. 5A. FIG. 5D is a cross section of the multi-channel device shown in FIG. 5A taken along a line extending between the brackets labeled D in FIG. 5A.

A first recess 71 extends through the silicon light-transmitting medium 30 and the silica insulator 34. A second recess 72 extends into the bottom of the first recess 71 such that the silicon substrate 36 forms shelves 73 in the bottom of the second recess 72. A first conducting layer 75 is positioned in the bottom of the second recess 72. A first conductor 76 on the silicon slab is in electrical communication with the first conducting layer 75. A second conductor 77 on the silicon slab is positioned adjacent to the first recess 71.

A gain element 10 is positioned in the first recess 71 and rests on the shelves 73. The gain element 10 includes a gain medium 12. A second conducting layer 78 is positioned on the gain medium 12. A third conductor 79 provides electrical communication between the second conducting layer 78 and the second conductor 77.

Three ridges extend into the second recess 72. The outer-most ridges have a passivation layer. The central ridge defines a portion of the gain waveguide 14 and is in electrical communication with the first conducting layer 75. The electrical communication between the central ridge and the first conducting layer 75 can be achieved through a conducting medium 80 such as solder. Since the first conductor 76 is in electrical communication with the first conducting layer 75, the first conductor 76 is in electrical communication with the central ridge.

The beam of light can be generated from the gain medium 12 by causing an electrical current to flow through the gain medium 12. The electrical current can be generated by applying a potential difference between the first conductor 76 and the second conductor 77. The potential difference can be provided by the electronics. The electronics can be included on the device or can be separate from the device but electrically coupled with the device.

The gain element 10 includes a reflecting surface on the gain medium 12. The reflecting surface can serve as the reflector 28 of FIG. 1. Suitable reflecting surfaces include a layer of metal on the layer of gain medium 12. The side of the gain medium 12 opposite the reflecting surface optionally includes an anti-reflective coating 82. The beam of light exits the gain medium 12 through the anti-reflective coating 82. Suitable anti-reflective coatings 82 include, but are not limited to, single-layer coatings such as silicon nitride or aluminum oxide, or multilayer coatings which may contain silicon nitride, aluminum oxide, and/or silica.

As is evident from FIG. 5A, the facet 84 for the cavity waveguide 16 can be angled at less than ninety degrees relative to the direction of propagation in the cavity waveguide 16. Angling the facet 84 at less than ninety degrees can cause light signals reflected at the facet 84 to be reflected out of the waveguide and can accordingly reduce issues associated with back reflection. Additionally or alternately, a facet of the gain waveguide can be angled at less than ninety degrees relative to the direction of propagation in the gain waveguide.

Suitable gain elements 10 include, but are not limited to, InP chips. The electrical communication between the second conducting layer 78 and the second conductor 77 can be achieved using traditional techniques such as wire bonding. The electrical communication between the central ridge and the first conductor 76 can be achieved through traditional techniques such as solder bonding.

Although FIG. 1 shows the gain element 10 positioned at an edge of the device, the gain element 10 can be located centrally on the device as shown in FIG. 5A through FIG. 5D.

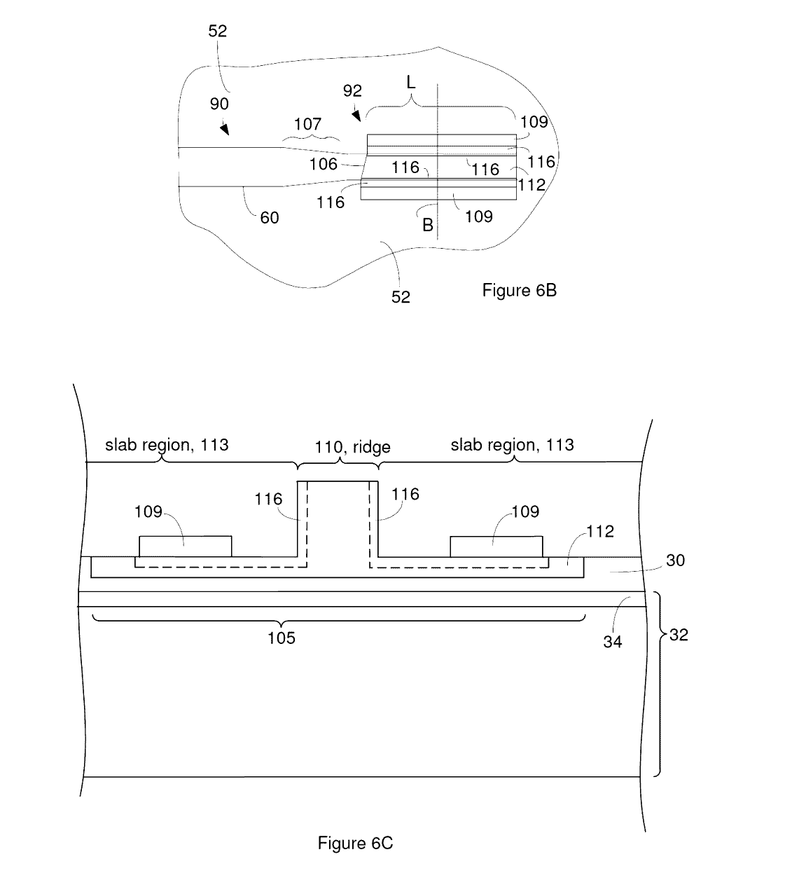

FIG. 6A through FIG. 6C illustrate a suitable receiver for use in an optical link such as the optical link of FIG. 4B. FIG. 6A is a topview of a schematic for a receiver. The receiver includes an input waveguide 90 that receives the light signal from the optical fiber 44 and uses the received light signal as an input signal. The input waveguide 90 guides the input signal to a light sensor 92. The light sensor 92 is in electrical communication with the electronics (not shown). The electronics are configured to operate each light sensor 92 such that the light sensor 92 outputs an electrical signal indicating the presence and/or intensity of the sensor signal received by the light sensor 92. In some instances, the electronics can process the electrical signals so as to extract data that was encoded onto the received light signals by a modulator included on the transmitter.

The receiver of FIG. 6A can be constructed on a variety of different platforms such as a silicon-on-insulator wafer. FIG. 6B is a topview of a portion of a receiver that is built on a silicon-on-insulator wafer and that includes the light sensor 92. FIG. 6C is a cross section of the light sensor shown in FIG. 6B taken along the line labeled B. A ridge 110 of light-absorbing medium 112 extends upward from a slab region 113 of the light-absorbing medium 112. The slab region of the light-absorbing medium 112 and the ridge 110 of the light-absorbing medium 112 are both positioned on a seed portion 105 of the light-transmitting medium 30. The seed portion 105 of the light-transmitting medium 30 is positioned on the base 32. As a result, the seed portion 105 of the light-transmitting medium 30 is between the light-absorbing medium 112 and the base 32. In some instances, the seed portion 105 of the light-transmitting medium 30 contacts the insulator 34.

The seed portion 105 of the light-transmitting medium 30 can be continuous with the light-transmitting medium 30 included in the input waveguide 90 or spaced apart from the input waveguide 90. When the light signal enters the light sensor 92, a portion of the light signal can enter the seed portion 105 of the light-transmitting medium 30 and another portion of the light signal can enter the light-absorbing medium 112. Accordingly, the light-absorbing medium 112 can receive only a portion of the light signal. In some instances, the light sensor can be configured such that the light-absorbing material receives the entire light signal.

During the fabrication of the device, the seed portion 105 of the light-transmitting medium 30 can be used to grow the light-absorbing medium 112. For instance, when the light-transmitting medium 30 is silicon and the light-absorbing medium 112 is germanium, the germanium can be grown on the silicon using a process such as epitaxial growth. As a result, the use of the light-transmitting medium 30 in both the input waveguide 90 and as a seed layer for growth of the light-absorbing medium 112 can simplify the process for fabricating the device.

As is evident from FIG. 6B, there is an interface 106 between a facet of the light-absorbing medium 112 and a facet of the light-transmitting medium 30. The interface can have an angle that is non-perpendicular relative to the direction of propagation of light signals through the input waveguide 90 at the interface. In some instances, the interface is substantially perpendicular relative to the base 32 while being non-perpendicular relative to the direction of propagation. The non-perpendicularity of the interface reduces the effects of back reflection. Suitable angles for the interface relative to the direction of propagation include but are not limited to, angles between 80° and 89°, and angles between 80° and 85°.

The input waveguide 90 optionally includes a taper 107. The taper 107 can be a horizontal taper and need not include a vertical taper although a vertical taper is optional. The taper 107 is positioned before the light sensor 92. For instance, the horizontal taper occurs in the light-transmitting medium 30 rather than in the light-absorbing medium 112. The taper 107 allows the light-absorbing medium 112 to have a narrower width than the input waveguide 90. The reduced width of the light-absorbing medium 112 increases the speed of the light sensor 92. The optical component preferably excludes additional components between the taper and light sensor although other components may be present.

During operation of the light sensor 92, a reverse bias electrical field is applied across the light-absorbing medium 112. When the light-absorbing medium 112 absorbs a light signal, an electrical current flows through the light-absorbing medium 112. As a result, the level of electrical current through the light-absorbing medium 112 indicates receipt of a light signal. Additionally, the magnitude of the current can indicate the power and/or intensity of the light signal. Different light-absorbing media 112 can absorb different wavelengths and are accordingly suitable for use in a light sensor 92 depending on the function of the light sensor 92. A light-absorbing medium 112 that is suitable for detection of light signals used in communications applications includes, but are not limited to, germanium, silicon germanium, silicon germanium quantum well, GaAs, and InP. Germanium is suitable for detection of light signals having wavelengths in a range of 1300 nm to 1650 nm.

Doped regions 116 of the light-absorbing medium 112 are positioned on the lateral sides of the ridge 110 of the light-absorbing medium 112. The doped regions 116 extend from the ridge 110 into the slab region of the light-absorbing medium 112. The transition of a doped region 116 from the ridge 110 of the light-absorbing medium 112 into the slab region of the light-absorbing medium 112 can be continuous and unbroken as is evident from FIG. 6C.

Each of the doped regions 116 can be an N-type doped regions or a P-type doped region. For instance, each of the N-type doped regions can include an N-type dopant and each of the P-type doped regions can include a P-type dopant. In some instances, the light-absorbing medium 112 includes a doped region 116 that is an N-type doped region and a doped region 116 that is a P-type doped region. The separation between the doped regions 116 in the light-absorbing medium 112 results in the formation of PIN junction in the light sensor 92.

In the light-absorbing medium 112, suitable dopants for N-type regions include, but are not limited to, phosphorus and/or arsenic. Suitable dopants for P-type regions include, but are not limited to, boron. The doped regions 116 are doped so as to be electrically conducting. A suitable concentration for the P-type dopant in a P-type doped region includes, but is not limited to, concentrations greater than 1×10¹⁵ cm⁻³, 1×10¹⁷ cm⁻³, or 1×10¹⁹ cm⁻³, and/or less than 1×10¹⁷ cm⁻³, 1×10¹⁹ cm⁻³, or 1×10²¹ cm⁻³. A suitable concentration for the N-type dopant in an N-type doped region includes, but is not limited to, concentrations greater than 1×10¹⁵ cm⁻³, 1×10¹⁷ cm⁻³, or 1×10¹⁹ cm⁻³, and/or less than 1×10¹⁷ cm⁻³, 1×10¹⁹ cm³, or 1×10²¹ cm⁻³.

Each doped region 116 is in contact with an electrical conductor 109 such as a metal. Accordingly, each of the doped regions 116 provides electrical communication between an electrical conductor 109 and a lateral side of the ridge of light-absorbing medium 112. As a result, electrical energy can be applied to the electrical conductors 109 in order to apply electrical energy to the lateral side of the ridge of light-absorbing medium 112. As a result, the resulting electrical field can be substantially parallel to the base 32.

A variety of other light sensor 92 constructions are suitable for use with waveguides on a silicon-on-insulator platform. For instance, the light sensor 92 can be constructed and/or operated as disclosed in U.S. patent application Ser. No. 12/380,016, filed Feb. 19, 2009, and entitled “Optical Device Having Light Sensor Employing Horizontal Electrical Field;” U.S. patent application Ser. No. 12/804,769, filed Jul. 28, 2010, and entitled “Light Monitor Configured to Tap Portion of Light Signal from Mid-Waveguide;” and/or in U.S. patent application Ser. No. 12/803,136, filed Jun. 18, 2010, and entitled “System Having Light Sensor with Enhanced Sensitivity;” and/or in U.S. patent application Ser. No. 12/799,633, filed Apr. 28, 2010, and entitled “Optical Device Having Partially Butt-Coupled Light Sensor;” and/or in U.S. patent application Ser. No. 12/589,501, filed Oct. 23, 2009, and entitled “System Having Light Sensor with Enhanced Sensitivity;” and/or in U.S. patent application Ser. No. 12/584,476, filed Sep. 4, 2009, and entitled “Optical Device Having Light Sensor Employing Horizontal Electrical Field;” each of which is incorporated herein in its entirety.

Although the transmitter disclosed above is disclosed in the context of a transmitter having a single laser cavity, the transmitter can include multiple laser cavities. Additionally or alternately, the receiver can include multiple light sensors rather than the single light sensor disclosed above. Examples of suitable transmitters and receivers are disclosed in U.S. patent application Ser. No. 14/280,067, filed on May 16, 2014 and entitled “Reducing Power Requirements for Optical Links” and also in U.S. patent application Ser. No. 14/048,685, filed on Oct. 8, 2013 and entitled “Use of Common Active Materials in Optical Components,” each of which is incorporated herein in its entirety.

### EXAMPLE 1

A transmitter having a first laser cavity according to FIG. 1 and FIG. 4A was constructed on a silicon-on-insulator wafer. The laser cavity had a grating length of 430 um, a passive section length of 160 um, a recess depth (dr in FIG. 2A) of 400 nm, a recess width (rw in FIG. 2A) of 335 nm, a gain medium length of 450 um. The output profile for the first laser is present in FIG. 3A. FIG. 3B shows the power of the light signal output from the laser cavity as a function of the bias current applied to the laser cavity. FIG. 3C shows the wavelength of the light signal output from the laser cavity as a function of the bias current applied to the laser cavity.

### EXAMPLE 2

A mode hop occurs when a current of about 80 mA is applied to the gain medium in the transmitter of Example 1 and the laser cavity is at a temperature of 60° C. The laser cavity is configured such that the wavelength error for the mode hop is 0.27 nm, and the power variation for this mode hop is 0.172 mW. Since the most intensely output mode in FIG. 3A is the fundamental mode, the SideMode Suppression Ratio (SMSR) is 35.13 dB.

The transmitter was included in optical links with different data travel distances and eye diagrams were generated using a data rate of 25 Gb/s. The applied current was swept from 40 to 100 mA. At a data travel distance of 500 m, a Bit Error Rate (BER) of 10⁻¹² was achieved and did not substantially change in response to the mode hop at the current level of about 80 mA. At a data travel distance of 1 km, a BER of 10⁻¹¹ was achieved and did not substantially change in response to the mode hop. At a data travel distance of 2 km, a BER of 10⁻⁹ was achieved and did not substantially change in response to the mode hop.

Other embodiments, combinations and modifications of this invention will occur readily to those of ordinary skill in the art in view of these teachings. Therefore, this invention is to be limited only by the following claims, which include all such embodiments and modifications when viewed in conjunction with the above specification and accompanying drawings.

1. An optical system, comprising:
a laser cavity on a substrate, the laser cavity outputting a laser light signal that exhibits one or more longitudinal mode hops;
the laser cavity having a SideMode Suppression Ratio (SMSR) that is less than 100 dB and greater than 40 dB;
the laser cavity having a wavelength error greater than 0.15 nm and less than 0.25 nm for one or more of the mode hops;
the laser cavity having a power variation is greater than −4 dBm and less than 0.2 dBm for one or more of the mode hops.

2. The system of claim 1, wherein the wavelength error for a first one of the mode hops is greater than 0.178 nm and less than 0.239 nm and the power variation for the first mode hop is greater than −3 dBm and less than 0.1 dBm.

3. The system of claim 1, wherein an optical link includes a transmitter that includes the laser cavity, the optical link has a receiver that receives an output light signal from the transmitter, the output light signal including light from the laser light signal.

4. The system of claim 3, wherein the output light signal travels a data travel distance between the transmitter and the receiver, the data travel distance being greater than 0.5 m and less than 1 km.

5. The system of claim 4, wherein a Bit Error Rate for the system is less than 10⁻¹².

6. The system of claim 4, wherein the data travel distance is less than 500 m.

7. The system of claim 4, wherein the laser cavity includes a cavity waveguide guiding a laser light signal between a gain medium and a partial return device,
the partial return device positioned to receive the laser light signal from the cavity waveguide and to return a first portion of the laser light signal to the cavity waveguide and to transmit a second portion of the laser light signal onto an output waveguide.

8. The system of claim 7, wherein the cavity waveguide guides the laser light signal through a medium that is different from the gain medium.

9. The system of claim 7, wherein the partial return device is a Bragg grating.

10. The system of claim 1, wherein each of the one or more mode hops occur when operating the laser cavity in a functional operational range, the functional operating range occurring at temperatures greater than 55° C. and less than 65° C. and at an applied current greater than 75 mA and less than 100 mA, where the applied current is an amount of electrical current that flows through a gain medium included in the laser cavity.

11. The system of claim 1, wherein the substrate is included in a silicon-on-insulator wafer.

12. The system of claim 1, wherein the laser cavity is an External Cavity Laser.

13. An optical link, comprising:
a transmitter that outputs a laser light signal, the transmitter including a laser cavity configured to longitudinally mode hop during operation of the optical link; and
a receiver that receives an output light signal from the transmitter, the output light signal including light from the laser light signal, the output light signal traveling a data travel distance between the transmitter and the receiver, the data travel distance being greater than 0.1 m and less than 1 km; and
the optical link having a Bit Error Rate less than 10⁻¹².

14. The link of claim 13, wherein the laser cavity has at least one condition selected from a group consisting of a wavelength error that is greater than 0.15 nm and less than 0.30 for at least one of the mode hops, a power variation that is greater than −10 dBm and less than 0.6 dBm, and a SideMode Suppression Ratio (SMSR) that is less than 100 dB and greater than 30 dB.

15. The link of claim 14, wherein the laser cavity has three of the conditions.

16. The link of claim 13, wherein the laser cavity is included in an external cavity laser.

17. The link of claim 13, wherein the laser cavity includes a cavity waveguide guiding a laser light signal between a gain medium and a partial return device,
the partial return device positioned to receive the laser light signal from the cavity waveguide and to return a first portion of the laser light signal to the cavity waveguide and to transmit a second portion of the laser light signal onto an output waveguide.

18. The link of claim 17, wherein the cavity waveguide guides the laser light signal through a medium that is different from the gain medium.

19. The link of claim 18, wherein the partial return device is a Bragg grating.

20. The link of claim 13, wherein each of the one or more mode hops occur when operating the laser cavity in a functional operational range, the functional operating range occurring at temperatures greater than 55° C. and less than 65° C. and at an applied current greater than 75 mA and less than 100 mA, where the applied current is an amount of electrical current that flows through a gain medium included in the laser cavity
